(19) United States
(12) Patent Application Publication
(10) Pub. No.: US 2026/0354123 A1
(43) Pub. Date: Nov. 5, 2026

(54) SEMICONDUCTOR DEVICE

(71) Applicant: Mitsubishi Electric Corporation, Tokyo (JP)

(72) Inventors: Shota O, Tokyo (JP); Seiya NAKANO, Tokyo (JP)

(73) Assignee: Mitsubishi Electric Corporation, Tokyo (JP)

(21) Appl. No.: 19/530,492

(22) Filed: Feb. 5, 2026

(30) Foreign Application Priority Data
May 1, 2025 (JP) 2025-076038

(51) Int. Cl. H10P 74/00

(52) U.S. Cl. CPC H10P 74/273

(57) ABSTRACT

A semiconductor device according to the present disclosure includes: an upper surface electrode formed on a first main surface of a semiconductor substrate; and a lower surface electrode formed on a second main surface on a side opposite to the first main surface and having main current flowing between the upper surface electrode and the lower surface electrode, wherein the upper surface electrode includes: a main output part outputting the main current in a plan view; a sense part outputting sense potential for detecting the main current; and a protruding part in which a part of the upper surface electrode protrudes toward an outer part, and at least one of the sense part and the main output part is provided to a position other than the protruding part.

### BACKGROUND

### Technical Field

The present disclosure relates to a semiconductor device, and particularly relates to a semiconductor device including a main output part outputting main current on a main electrode and a sensing part outputting sense voltage.

### Description of the Background Art

A semiconductor device may include a main output part in which main current flows and a sense part in which small current flows to detect sense voltage in some cases. Normally, the main output part and the sense part are electrically connected via a metal electrode such as an emitter electrode, for example, and are designed to have potential as nearly equal as possible.

For example, Japanese Patent Application Laid-Open No. 2009-295845 discloses a technique of reducing a distance from a main-side terminal provided on a source electrode to a voltage detection terminal, thereby reducing a difference of potential between main potential of the main-side terminal and sense potential of the voltage detection terminal.

### SUMMARY

However, since voltage drop necessarily occurs in accordance with a distance from the main output part and the sense part, there is a possibility that a state where potential is different between the main output part and the sense part and accuracy of voltage measurement decreases.

An object is to provide a semiconductor device capable of reducing voltage drop between a main output part and a sense part and measuring voltage with higher accuracy.

A semiconductor device according to the present disclosure includes: an upper surface electrode formed on a first main surface of a semiconductor substrate; and a lower surface electrode formed on a second main surface on a side opposite to the first main surface and having main current flowing between the upper surface electrode and the lower surface electrode, wherein the upper surface electrode includes: a main output part outputting the main current in a plan view; a sense part outputting sense potential for detecting the main current; and a protruding part in which a part of the upper surface electrode protrudes toward an outer part, and at least one of the sense part and the main output part is provided to a position other than the protruding part.

According to the semiconductor device of the present disclosure, a conduction region of the main output part and the sense part increases and voltage drop between the main output part and the sense part decreases. Thus, voltage can be measured with higher accuracy. Since at least one of the sense part and the main output part is provided to the position other than the protruding part, increase of a wire height caused by bonding the wire thereon can be suppressed.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view schematically illustrating an upper surface configuration of a whole semiconductor device according to an embodiment 1 of the present disclosure.

FIG. 2 is a partial cross-sectional view illustrating a configuration of the semiconductor device according to the embodiment 1 of the present disclosure.

FIG. 3 is a plan view schematically illustrating an upper surface configuration of a whole semiconductor device according to an embodiment 2 of the present disclosure.

FIG. 4 is a partial cross-sectional view illustrating a configuration of the semiconductor device according to the embodiment 2 of the present disclosure.

FIG. 5 is a plan view schematically illustrating an upper surface configuration of a whole semiconductor device according to an embodiment 3 of the present disclosure.

FIG. 6 is a partial cross-sectional view illustrating a configuration of the semiconductor device according to the embodiment 3 of the present disclosure.

FIG. 7 is a plan view schematically illustrating an upper surface configuration of a whole semiconductor device according to an embodiment 4 of the present disclosure.

FIG. 8 is a partial cross-sectional view illustrating a configuration of the semiconductor device according to the embodiment 4 of the present disclosure.

FIG. 9 is a partial cross-sectional view illustrating a configuration of a semiconductor device according to an embodiment 5 of the present disclosure.

FIG. 10 is a partial cross-sectional view illustrating a configuration of a semiconductor device according to an embodiment 6 of the present disclosure.

FIG. 11 is a plan view schematically illustrating an upper surface configuration of a whole semiconductor device according to an embodiment 7 of the present disclosure.

FIG. 12 is a partial cross-sectional view illustrating a configuration of a semiconductor device according to an embodiment 7 of the present disclosure.

FIG. 13 is a partial cross-sectional view illustrating a configuration of a semiconductor device according to an embodiment 8 of the present disclosure.

FIG. 14 is a plan view schematically illustrating an upper surface configuration of a whole semiconductor device according to an embodiment 9 of the present disclosure.

### DESCRIPTION OF THE PREFERRED EMBODIMENTS

### Introduction

In the description hereinafter, an n type and a p type indicate a conductivity type of a semiconductor, and a first conductivity type is an n type and a second conductivity type is a p type in the present disclosure; however, the first conductivity type may be a p type, and the second conductivity type may be an n type. An n⁻ type indicates that an impurity concentration thereof is lower than that of the n type, and an n⁺ type indicates that an impurity concentration thereof is higher than that of the n type. In the similar manner, a p⁻ type indicates that an impurity concentration thereof is lower than that of the p type, and a p⁺ type indicates that an impurity concentration thereof is higher than that of the p type.

Since the diagrams are schematically illustrated, a mutual relationship of sizes and positions of images respectively illustrated in the different diagrams is not necessarily illustrated accurately, but may be appropriately changed. In the description hereinafter, the same reference numerals will be assigned to the similar constituent elements in the diagrams, and the constituent elements having the same reference numeral have the similar name and function. Accordingly, the detailed description on them may be omitted in some cases.

Used in some cases are terms each indicating a specific position and direction such as “up”, “down”, “side”, “front”, and “back”, for example; however, these terms are used for convenience of easy understanding of contents of the embodiments, and do not relate to a direction in an actual use.

### Embodiment 1

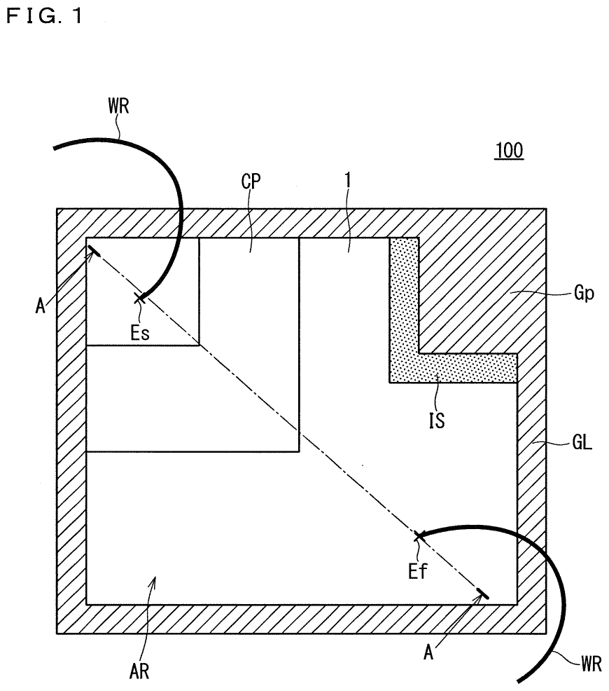

FIG. 1 is a plan view schematically illustrating an upper surface configuration of a whole insulated gate bipolar transistor (IGBT) 100 according to an embodiment 1 of the present disclosure. The IGBT 100 illustrated in FIG. 1 has a quadrangular outer shape, and a major part thereof is an active region AR in which a plurality of minimum unit structures of the IGBTs (IGBT cells) referred to as “unit cells” are disposed and main current flows, and an upper part of the active region AR is covered by an emitter electrode 1. A gate wiring GL surrounds an outer surrounding of the active region AR and is connected to a gate pad GP provided to a corner part, and the gate pad GP is electrically separated from the active region AR by an insulating film IS.

A plurality of trench electrodes (not shown) are provided to the active region AR at interval in parallel to each. The plurality of trench electrodes are connected to the gate wiring GL.

A sense part Es outputting sense potential (emitter voltage) for detecting the main current is provided to one of the corner part of the active region AR covered by the emitter electrode 1 (an upper surface electrode), and a wire WR is bonded to the sense part Es. This wire WR is connected to a voltage measurement circuit not shown via a high resistance element.

A main output part Ef outputting the main current is provided to a corner part on a side opposite to the corner part in which the sense part Es is provided, and the wire WR is bonded to the main output part Ef. This wire WR is located to a load such as a motor not shown, for example. Although the main output part Ef is provided at one position and one wire WR is also provided in FIG. 1, this configuration is an example. It is also applicable that the main output parts Ef are provided at a plurality of positions and the wires WR are connected thereto, respectively.

A protruding part CP provided to the emitter electrode 1 is located between the sense part Es and the main output part Ef to constitute a configuration of reducing a difference of potential between the sense part Es and the main output part Ef. Although the protruding part CP is provided along two sides of the corner part in which the sense part Es is provided and has an L-like shape in a plan view, the shape is not limited thereto.

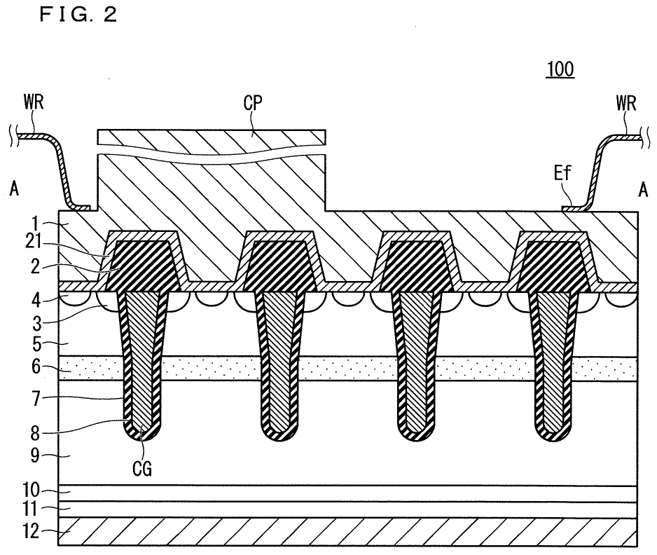

FIG. 2 is a cross-sectional view along an A-A broken line in an arrow direction in FIG. 1. As illustrated in FIG. 2, the plurality of gate electrodes CG are provided at intervals on a first main surface side as an upper surface of the semiconductor substrate such as a silicon substrate in the IGBT 100.

The gate electrode CG is buried in a trench 7 formed in the semiconductor substrate via a gate insulating film 8 to constitute a trench electrode. The gate electrode CG is electrically connected to a gate pad (FIG. 1), and a gate signal is supplied to the gate electrode CG.

As illustrated in FIG. 2, the IGBT 100 includes an ⁻-type drift layer 9 made up of the semiconductor substrate. The n⁻-type drift layer 9 is a semiconductor layer having arsenic (As) or phosphorus (P), for example, as an n-type impurity.

A p-type base layer 5 is provided to an upper layer part as the first main surface side of the n⁻-type drift layer 9. The p-type base layer 5 is a semiconductor layer having boron (B) or aluminum (Al), for example, as a p-type impurity, and has contact with the gate insulating layer 8 of the gate electrode CG.

An n⁺-type source layer 3 is provided to an upper layer part of the p-type base layer 5 to have contact with the gate insulating film 8 of the gate electrode CG. The n⁺-type source layer 3 is a semiconductor layer having arsenic or phosphorus, for example, as the n-type impurity.

A p⁺-type contact layer 4 is provided between the n⁺-type source layers 3 adjacent to each other in the upper layer part of the p-type base layer 5. The p⁺-type contact layer 4 is a semiconductor layer having boron or aluminum, for example, as a p-type impurity.

An n-type carrier accumulation layer 6 having a higher concentration of an n-type impurity than the n⁻-type drift layer 9 is provided to have contact with the gate insulating film 8 of the gate electrode CG in the n⁻-type drift layer 9 in a lower part of the p-type base layer 5. The n-type carrier accumulation layer 6 is a semiconductor layer having arsenic or phosphorus, for example, as the n-type impurity.

A p-type collector layer 11 and an n-type buffer layer 10 are provided to a second main surface side as a lower surface of the semiconductor substrate in this order from second main surface, and a collector electrode 12 (lower surface electrode) is provided on the second main surface on a side opposite to the emitter electrode 1.

The n-type buffer layer 10 is a semiconductor layer having arsenic or phosphorus, for example, as an n-type impurity.

The p-type collector layer 11 is a semiconductor layer having boron or aluminum, for example, as a p-type impurity, and constitutes the second main surface of the semiconductor substrate.

The gate electrode CG can be made of polysilicon doped with an n-type or p-type impurity.

The emitter electrode 1 can be formed of aluminum alloy such as aluminum silicon alloy (Al—Si series alloy), for example.

The collector electrode 12 can be formed by depositing aluminum silicon alloy (Al—Si series alloy) or titanium (Ti) by physical vapor deposition such as sputtering or vapor deposition, and can also be formed by laminating plural types of metal such as aluminum silicon alloy, titanium, nickel, and gold.

An interlayer insulating film 2 is provided on the gate electrode CG. The interlayer insulating film 2 can be formed of a silicon oxide film (SiO₂), for example.

A barrier metal 21 is formed on a region in which the interlayer insulating film 2 is not provided on the first main surface of the semiconductor substrate and on the interlayer insulating film 2. The barrier metal 21 can be a conductor including titanium (Ti), and can be made of TiSi in which titanium nitride or titanium and silicon (Si) are alloyed, for example. The barrier metal 21 has ohmic contact with the n⁺-type source layer 3 and the p⁺-type contact layer 4, and is electrically connected to the n⁺-type source layer 3 and the p⁺-type contact layer 4.

The emitter electrode 1 is provided on the barrier metal 21, but can also be provided on the n⁺-type source layer 3 without providing the barrier metal 21. The barrier metal 21 and the emitter electrode 1 may be collectively referred to as the emitter electrode.

As illustrated in FIG. 2, the emitter electrode 1 includes a protruding part CP in which upper sides of some gate electrodes CG protrude toward an outer part, and a part including the protruding part CP has a larger thickness than the emitter electrode 1 in the other part.

That is to say, the thickness of a part of the emitter electrode 1 other than the protruding part CP is approximately 5 μm. In the meanwhile, the thickness of the protruding part CP is approximately several millimeters, is set to conform to a wire height of the wire WR, thus is substantially the same as the wire height.

According to such a configuration, a conduction region of the main output part Ef and the sense part Es increases, and voltage drop between the main output part Ef and the sense part Es decreases.

As illustrated in FIG. 2, the main output part Ef and the sense part Es are provided to the part of the emitter electrode 1 other than the protruding part CP, that is to say, the part thereof having the small thickness, and the wire WR is bonded thereto. Thus, increase of the wire height can be suppressed, and a height of a package of a module can also be reduced when the IGBT 100 is incorporated into a semiconductor module.

In the meanwhile, when the region of the protruding part CP in the emitter electrode 1 is further increased and both the main output part Ef and the sense part Es are provided to the protruding part CP, the conduction region between the main output part Ef and the sense part Es is further increased, and the voltage drop further decreases.

A dimension (chip size) of the IGBT 100 in a chip state in a plan view can be 1 mm to 150 mm in one side, for example, and one side has the size of approximately 5 mm to 15 mm in many cases in current conditions. As the chip size increases, the distance from the main output part Ef and the sense part Es gets longer; thus, an effect caused by providing the protruding part CP increases.

Connection of the main output part Ef and the sense part Es to the outer part is not limited to wire bonding. The main output part Ef and the sense part Es can also be connected to the outer side via a conductor plate made of copper such as direct lead bonding. In this case, a height of a connection part between the conductor plate and the emitter electrode 1 is approximately several hundred micrometers.

### Embodiment 2

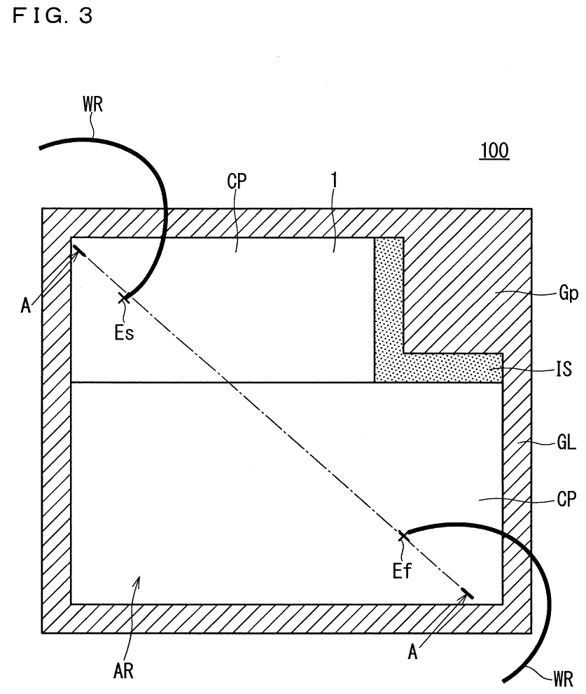

FIG. 3 is a plan view schematically illustrating an upper surface configuration of a whole IGBT 200 according to an embodiment 2 of the present disclosure. In FIG. 3, the same reference numerals are assigned to the same configuration as the IGBT 100 described using FIG. 1, and a repetitive description will be omitted.

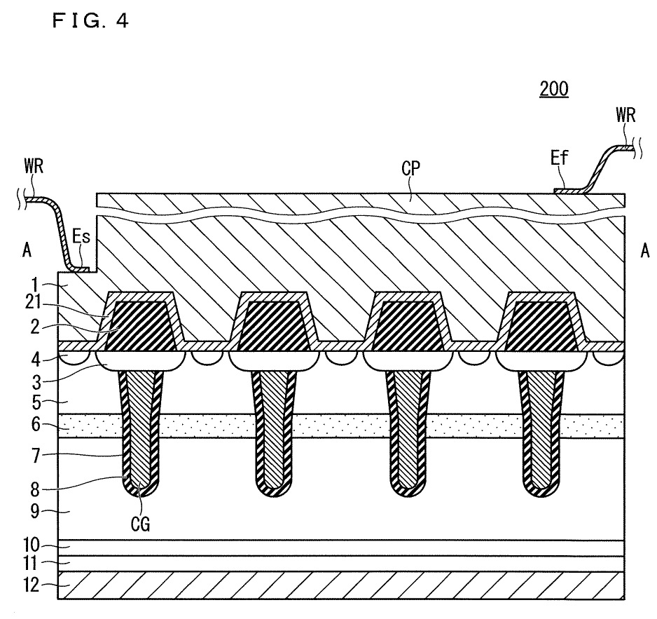

In the IGBT 200, the protruding part CP is provided to cover more than half of the active region AR as illustrated in FIG. 3, and the main output part Ef is provided on the protruding part CP. FIG. 4 is a cross-sectional view along an A-A broken line in an arrow direction in FIG. 3. In FIG. 4, the same reference numerals are assigned to the same configuration as the IGBT 100 described using FIG. 2, and a repetitive description will be omitted.

As illustrated in FIG. 4, the emitter electrode 1 includes the protruding part CP in which the upper sides of the large number of gate electrodes CG protrude toward outside, and the part including the protruding part CP has a larger thickness than the emitter electrode 1 in the other part in the IGBT 200. This thickness is the same as that of the IGBT 100 described using FIG. 2.

According to such a configuration, the conduction region of the main output part Ef and the sense part Es further increases, and voltage drop between the main output part Ef and the sense part Es further decreases.

### Embodiment 3

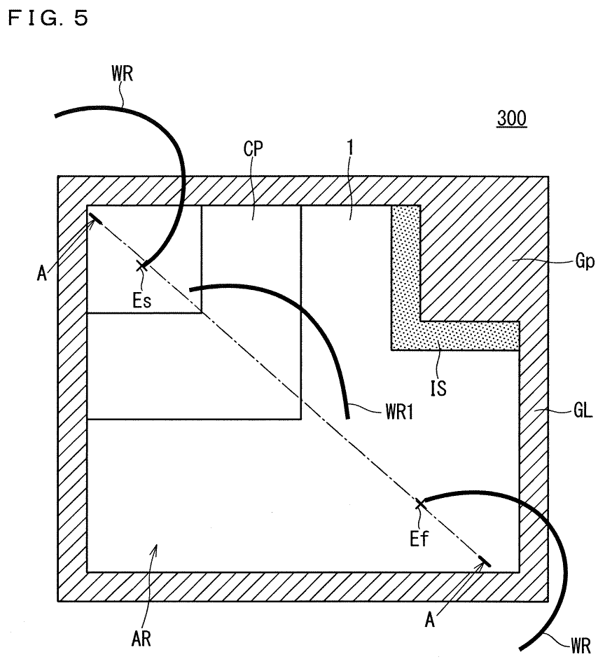

FIG. 5 is a plan view schematically illustrating an upper surface configuration of a whole IGBT 300 according to an embodiment 3 of the present disclosure. In FIG. 5, the same reference numerals are assigned to the same configuration as the IGBT 100 described using FIG. 1, and a repetitive description will be omitted.

The protrusion part CP provided to the emitter electrode 1 is located between the sense part Es and the main output part Ef as illustrated in FIG. 5 to constitute a configuration of reducing the difference of potential between the sense part Es and the main output part Ef, and a bypass wire WR1 is provided to extend over the protruding part CP in the IGBT 300.

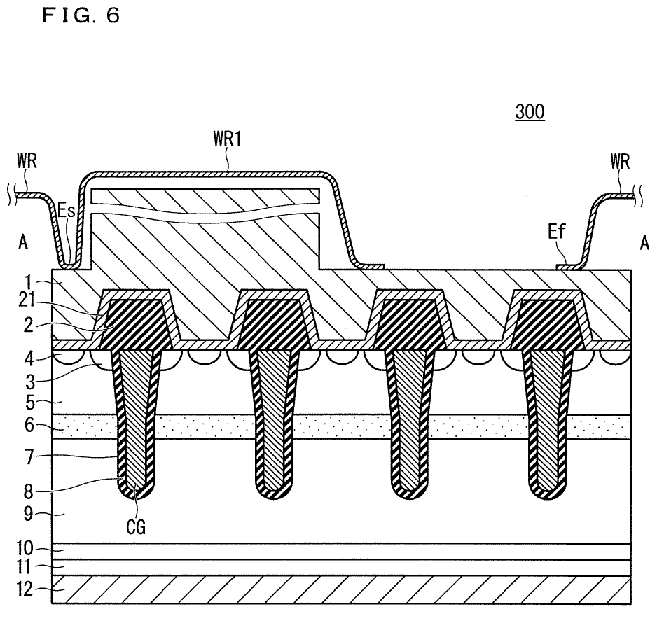

FIG. 6 is a cross-sectional view along an A-A broken line in an arrow direction in FIG. 5. In FIG. 5, the same reference numerals are assigned to the same configuration as the IGBT 100 described using FIG. 2, and a repetitive description will be omitted.

When the bypass wire WR1 is provided, the conduction region between the main output part Ef and the sense part Es further increases, and the voltage drop further decreases.

Aluminum, gold, and silver can be used as a material of the bypass wire WR1. The number of the bypass wires WR1 is not limited to one. The plurality of bypass wires WR1 can be provided, and when the number of wires WR1 is increased, the conduction region between the main output part Ef and the sense part Es can be increased.

### Embodiment 4

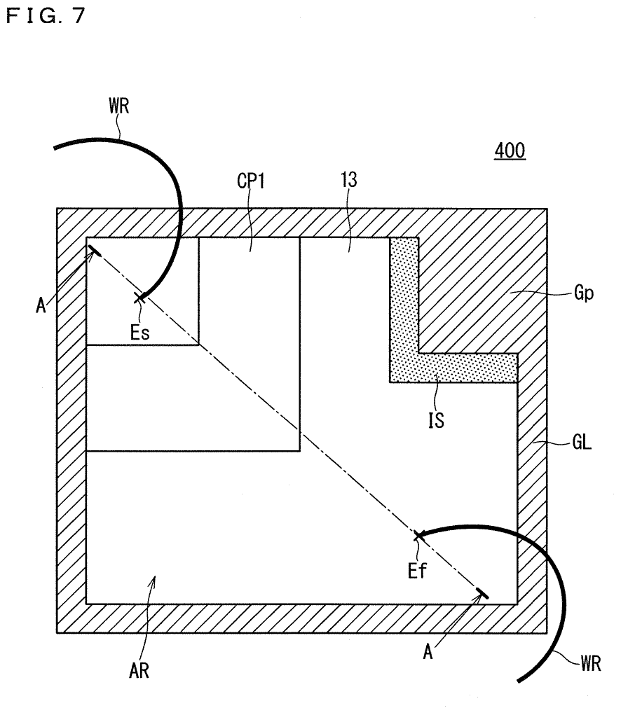

FIG. 7 is a plan view schematically illustrating an upper surface configuration of a whole IGBT 400 according to an embodiment 4 of the present disclosure. In FIG. 7, the same reference numerals are assigned to the same configuration as the IGBT 100 described using FIG. 1, and a repetitive description will be omitted.

In the IGBT 400, the upper part of the active region AR is covered by the emitter electrode 1 (first upper surface electrode) not shown as illustrated in FIG. 7, an upper electrode 13 (second upper surface electrode) is provided further thereon, and the sense part Es and the main output part Ef are provided on the upper electrode 13.

The protruding part CP1 provided to the upper electrode 13 is located between the sense part Es and the main output part Ef to constitute a configuration of reducing a difference of potential between the sense part Es and the main output part Ef.

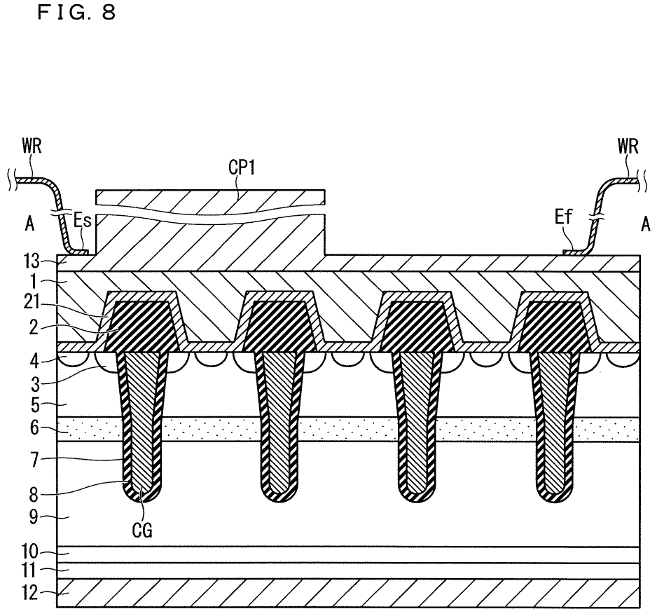

FIG. 8 is a cross-sectional view along an A-A broken line in an arrow direction in FIG. 7. In FIG. 8, the same reference numerals are assigned to the same configuration as the IGBT 100 described using FIG. 2, and a repetitive description will be omitted.

As illustrated in FIG. 8, provided on the flat emitter electrode 1 is a protruding part CP1 in which upper sides of some gate electrodes CG protrude toward outside, and the part including the protruding part CP1 has a larger thickness than the upper electrode 13 in the other part in the IGBT 400.

That is to say, the thickness of the upper electrode 13 other than the protruding part CP1 is approximately several micrometers. In the meanwhile, the thickness of the protruding part CP1 is approximately several millimeters, is set to conform to a wire height of the wire WR, thus is substantially the same as the wire height.

According to such a configuration, the conduction region of the main output part Ef and the sense part Es increases, and the voltage drop between the main output part Ef and the sense part Es decreases.

As illustrated in FIG. 8, the main output part Ef and the sense part Es are provided to the part of the upper electrode 13 other than the protruding part CP1, that is to say, the part thereof having the small thickness, and the wire WR is bonded thereto. Thus, increase of the wire height can be suppressed, and a height of a package of a module can also be reduced when the IGBT 400 is incorporated into a semiconductor module.

When a material of upper electrode 13 is different from that of the emitter electrode 1, a new effect can be obtained. For example, when the material of the upper electrode 13 is inexpensive than that of the emitter electrode 1, manufacturing cost can be reduced. When the material of the upper electrode 13 has lower electrical resistance than that of the emitter electrode 1, the voltage drop between the main output part Ef and the sense part Es can be reduced. When the material of the upper electrode 13 has higher corrosion resistance than that of the emitter electrode 1, reliability of a product can be increased.

Examples of the material of the upper electrode 13 can include nickel (Ni) or copper (Cu), and the upper electrode 13 can be formed by PVD such as sputtering or vapor deposition.

The configuration of providing the bypass wire WR1 to extend over the protruding part CP1 can also be applied to the embodiment 4 in the manner similar to the embodiment 3.

### Embodiment 5

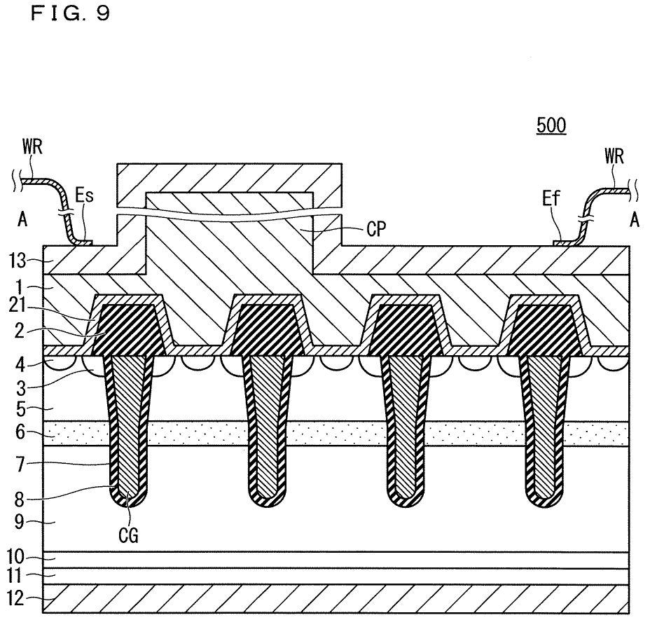

FIG. 9 is a cross-sectional view illustrating a configuration of an IGBT 500 according to an embodiment 5 in the present disclosure. In FIG. 9, the same reference numerals are assigned to the same configuration as the IGBT 100 described using FIG. 2, and a repetitive description will be omitted. An upper surface configuration of the whole IGBT 500 is similar to that of the IGBT 400 illustrated in FIG. 7, and FIG. 9 corresponds to a cross section in an A-A broken line in an arrow direction in FIG. 7.

As illustrated in FIG. 9, the emitter electrode 1 includes the protruding part CP in which the upper sides of some gate electrodes CG protrude toward outside, and the part including the protruding part CP has the larger thickness than the emitter electrode 1 in the other part.

That is to say, the thickness of the part of the emitter electrode 1 other than the protruding part CP is approximately 5 μm. In the meanwhile, the thickness of the protruding part CP is approximately several millimeters, is set to conform to the wire height of the wire WR, thus is substantially the same as the wire height.

The upper electrode 13 is provided to cover the whole upper surface of the emitter electrode 1 including the protruding part CP, and the sense part Es and the main output part Ef are provided on the upper electrode 13. The upper electrode 13 is a gold-plated film, for example. A thickness of a plated film is generally equal to or smaller than 1 μm, and is approximately 0.05 μm in consideration of cost. The plated film has an effect of preventing oxidation of the emitter electrode 1 and increasing performance of wire bonding to the emitter electrode 1.

The thickness of the protruding part CP of the emitter electrode 1 is approximately several millimeters. Thus, even when the upper electrode 13 is thin, the conduction region of the main output part Ef and the sense part Es increases, and the voltage drop between the main output part Ef and the sense part Es decreases.

As illustrated in FIG. 9, the main output part Ef and the sense part Es are provided to the part of the emitter electrode 1 other than the protruding part CP, that is to say, the part thereof having the small thickness with the thin upper electrode 13 therebetween, and the wire WR is bonded thereto. Thus, increase of the wire height can be suppressed, and a height of a package of a module can also be reduced when the IGBT 500 is incorporated into a semiconductor module.

The configuration of providing the bypass wire WR1 to extend over the protruding part CP can also be applied to the embodiment 5 in the manner similar to the embodiment 3.

### Embodiment 6

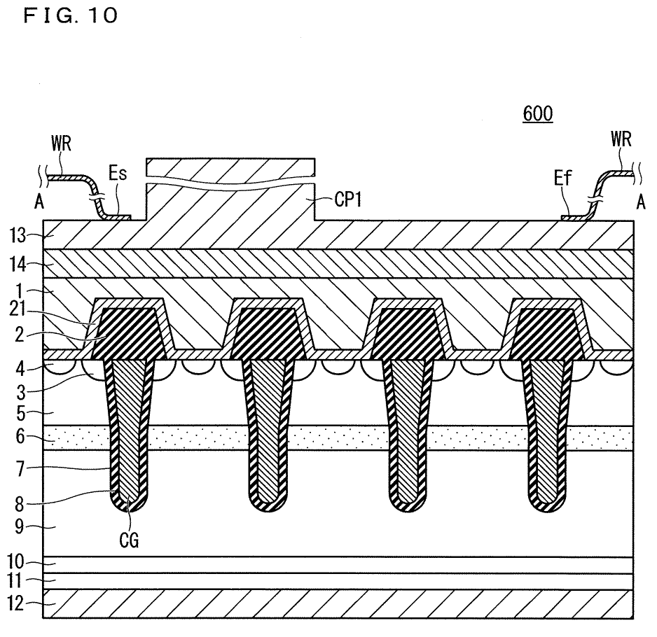

FIG. 10 is a cross-sectional view illustrating a configuration of an IGBT 600 according to an embodiment 6 in the present disclosure. In FIG. 10, the same reference numerals are assigned to the same configuration as the IGBT 100 described using FIG. 2, and a repetitive description will be omitted. An upper surface configuration of the whole IGBT 600 is similar to that of the IGBT 400 illustrated in FIG. 7, and FIG. 9 corresponds to a cross section in an A-A broken line in an arrow direction in FIG. 7.

As illustrated in FIG. 10, bonded to the flat emitter electrode 1 is the upper electrode 13 including the protruding part CP1 in which some gate electrodes CG protrude toward outside via a solder layer 14, and a part including the protruding part CP1 has a larger thickness than the upper electrode 13 in the other part in the IGBT 600.

That is to say, the thickness of the upper electrode 13 other than the protruding part CP1 is approximately several micrometers. In the meanwhile, the thickness of the protruding part CP1 is approximately several millimeters, is set to conform to a wire height of the wire WR, thus is substantially the same as the wire height.

According to such a configuration, the conduction region of the main output part Ef and the sense part Es increases, and the voltage drop between the main output part Ef and the sense part Es decreases.

As illustrated in FIG. 10, the main output part Ef and the sense part Es are provided to the part of the upper electrode 13 other than the protruding part CP1, that is to say, the part thereof having the small thickness, and the wire WR is bonded thereto. Thus, increase of the wire height can be suppressed, and a height of a package of a module can also be reduced when the IGBT 600 is incorporated into a semiconductor module.

When the thickness of the protruding part CP1 of the upper electrode 13 is approximately several millimeters, it is sufficient that a thick member is previously ground to prepare the upper electrode 13 including the protruding part CP1 and the upper electrode 13 is soldered to the emitter electrode 1 using solder. Thus, manufacturing cost is suppressed. A thickness of the solder layer 14 can be several tens micrometers to several hundred millimeters, and can be more preferably approximately 100 μm.

When the upper electrode 13 is formed by a film formation method such as PVD, heat diffusion and chemical reaction occur between the upper electrode 13 and the emitter electrode 1. However, since the upper electrode 13 is provided by soldering in the IGBT 600, the IGBT 600 is not influenced by the heat diffusion and the chemical reaction.

The configuration of providing the bypass wire WR1 to extend over the protruding part CP1 can also be applied to the embodiment 6 in the manner similar to the embodiment 3.

### Embodiment 7

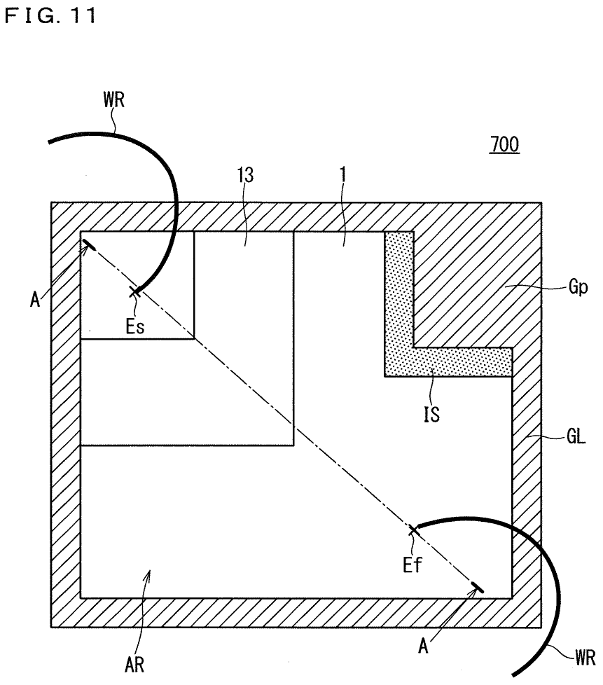

FIG. 11 is a plan view schematically illustrating an upper surface configuration of a whole IGBT 700 according to an embodiment 7 of the present disclosure. In FIG. 11, the same reference numerals are assigned to the same configuration as the IGBT 100 described using FIG. 1, and a repetitive description will be omitted.

In the IGBT 700, the upper electrode 13 is provided on the emitter electrode 1 between the sense part Es and the main output part Ef as illustrated in FIG. 11. Although the upper electrode 13 is provided along two sides of the corner part in which the sense part Es is provided and has an L-like shape in a plan view, the shape is not limited thereto.

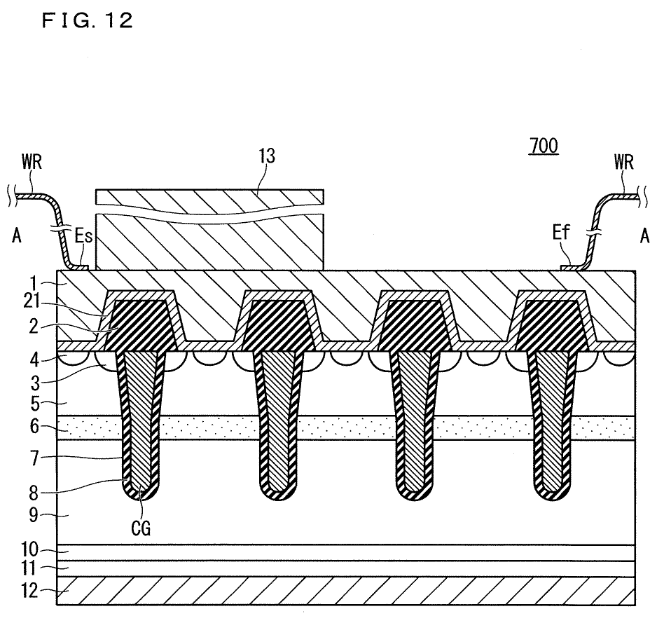

FIG. 12 is a cross-sectional view along an A-A broken line in an arrow direction in FIG. 11. In FIG. 12, the same reference numerals are assigned to the same configuration as the IGBT 100 described using FIG. 2, and a repetitive description will be omitted.

As illustrated in FIG. 12, in the IGBT 700, the upper electrode 13 is provided on the flat emitter electrode 1 above some gate electrodes CG. The thickness of the upper electrode 13 is approximately several millimeters, is set to conform to a wire height of the wire WR, thus is substantially the same as the wire height.

According to such a configuration, the upper electrode 13 functions as the protruding part CP or the protruding part CP1, the conduction region of the main output part Ef and the sense part Es increases, and the voltage drop between the main output part Ef and the sense part Es decreases.

As illustrated in FIG. 12, the main output part Ef and the sense part Es are provided on the emitter electrode 1, and the wire WR is bonded thereto. Thus, increase of the wire height can be suppressed, and a height of a package of a module can also be reduced when the IGBT 700 is incorporated into a semiconductor module.

When a material of upper electrode 13 is different from that of the emitter electrode 1, a new effect can be obtained. For example, when the material of the upper electrode 13 is inexpensive than that of the emitter electrode 1, manufacturing cost can be reduced. When the material of the upper electrode 13 has lower electrical resistance than that of the emitter electrode 1, the voltage drop between the main output part Ef and the sense part Es can be reduced. When the material of the upper electrode 13 has higher corrosion resistance than that of the emitter electrode 1, reliability of a product can be increased.

Examples of the material of the upper electrode 13 can include nickel (Ni) or copper (Cu), and the upper electrode 13 can be formed by PVD such as sputtering or vapor deposition.

The upper electrode 13 is a structure partially provided on the emitter electrode 1, thus has an advantage that the upper electrode 13 can be easily formed even in a case of being formed by PVD, for example.

The configuration of providing the bypass wire WR1 to extend over the upper electrode 13 can also be applied to the embodiment 7 in the manner similar to the embodiment 3.

### Embodiment 8

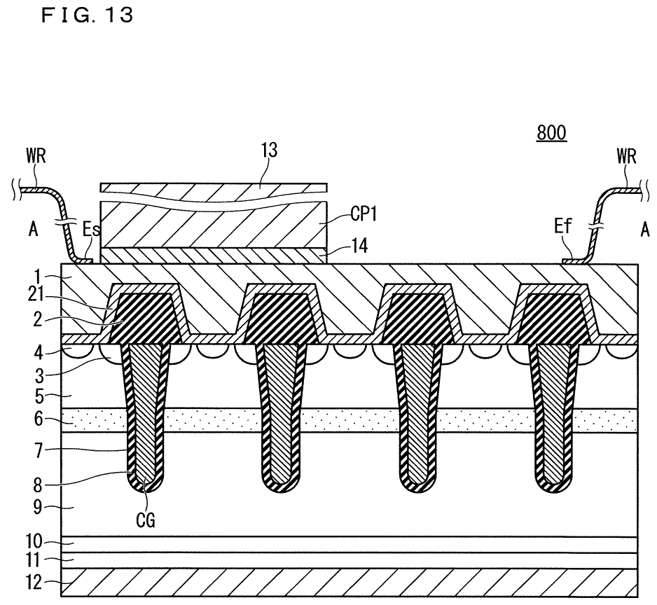

FIG. 13 is a cross-sectional view illustrating a configuration of an IGBT 800 according to an embodiment 8 in the present disclosure. In FIG. 13, the same reference numerals are assigned to the same configuration as the IGBT 100 described using FIG. 2, and a repetitive description will be omitted. An upper surface configuration of the whole IGBT 800 is similar to that of the IGBT 700 illustrated in FIG. 11, and FIG. 13 corresponds to a cross section in an A-A broken line in an arrow direction in FIG. 11.

As illustrated in FIG. 13, in the IGBT 800, the upper electrode 13 is provided on the flat emitter electrode 1 via the solder layer 14 above some gate electrodes CG. The thickness of the upper electrode 13 is approximately several millimeters, is set to conform to a wire height of the wire WR, thus is substantially the same as the wire height.

According to such a configuration, the conduction region of the main output part Ef and the sense part Es increases, and the voltage drop between the main output part Ef and the sense part Es decreases.

As illustrated in FIG. 13, the main output part Ef and the sense part Es are provided on the emitter electrode 1, and the wire WR is bonded thereto. Thus, increase of the wire height can be suppressed, and a height of a package of a module can also be reduced when the IGBT 800 is incorporated into a semiconductor module.

The thickness of the solder layer 14 can be several tens micrometers to several hundred millimeters. A conductive bonding material such as a silver paste can also be used in place of the solder layer 14.

When the upper electrode 13 is formed by a film formation method such as PVD, heat diffusion and chemical reaction occur between the upper electrode 13 and the emitter electrode 1. However, since the upper electrode 13 is provided by soldering or the conductive bonding material in the IGBT 800, the IGBT 800 is not influenced by the heat diffusion and the chemical reaction.

The upper electrode 13 is a structure partially provided on the emitter electrode 1, thus has an advantage that the upper electrode 13 can be easily formed even in a case of being formed by PVD, for example.

The configuration of providing the bypass wire WR1 to extend over the upper electrode 13 can also be applied to the embodiment 8 in the manner similar to the embodiment 3.

### Embodiment 9

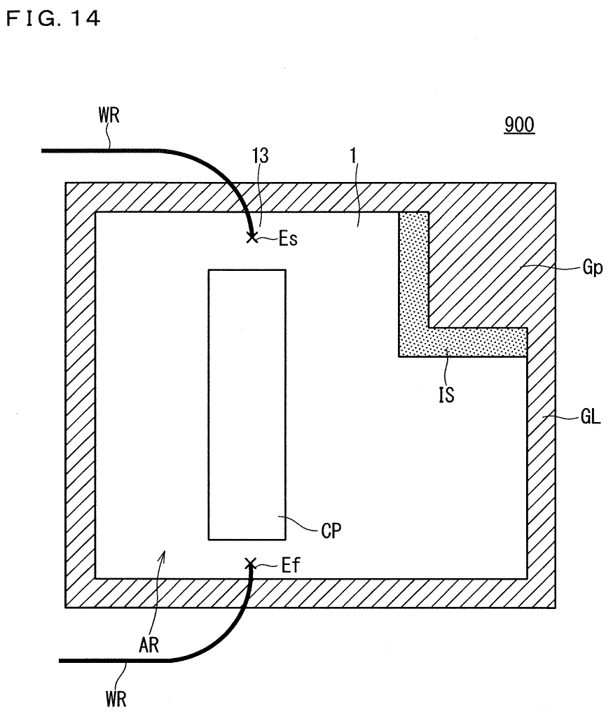

FIG. 14 is a plan view schematically illustrating an upper surface configuration of a whole IGBT 900 according to an embodiment 9 of the present disclosure. In FIG. 14, the same reference numerals are assigned to the same configuration as the IGBT 100 described using FIG. 1, and a repetitive description will be omitted.

In the IGBT 900, the protruding part CP provided to the emitter electrode 1 is located between the sense part Es and the main output part Ef as illustrated in FIG. 14 to constitute a configuration of reducing a difference of potential between the sense part Es and the main output part Ef.

The protruding part CP has a striped shape extending in a first direction as a direction linearly connecting the sense part Es and the main output part Ef in a plan view. Although FIG. 14 illustrates a configuration that the sense part Es and the main output part Ef are disposed near each of two sides facing each other of the IGBT 900 having a quadrangular shape, the arrangement of the sense part Es and the main output part Ef is not limited thereto.

According to such a configuration, when it is difficult to form the protruding part CP in a large area in accordance with a process condition and there is a problem in cost, for example, the problem can be solved by reducing the area of the protruding part CP as much as possible.

In not only the configuration of providing the protruding part CP to the emitter electrode 1 but also the configuration of providing the upper electrode 13 on the emitter electrode 1 as with the embodiment 7 described using FIG. 12, when the upper electrode 13 has a striped shape extending in the first direction as the direction linearly connecting the sense part Es and the main output part Ef in a plan view, the area of the upper electrode 13 is reduced as much as possible, and the similar problem can be solved.

The embodiments 1 to 9 described above describe the configuration of applying the present disclosure to the IGBT. However, the present disclosure can also be applied to a metal oxide semiconductor (MOS) transistor, a reverse conduction IGBT (RC-IGBT).

The present disclosure can be applied to not only a transistor including a trench electrode as the gate electrode but also a transistor including a planar electrode.

The semiconductor substrate used in the present disclosure is not limited to a silicon substrate. A wide bandgap semiconductor substrate including wide bandgap semiconductor such as silicon carbide (SiC) as a main material can also be used.

Each embodiment can be arbitrarily combined, or each embodiment can be appropriately varied or omitted within a scope of the present disclosure.

The present disclosure described above is collectively described hereinafter as appendixes.

### (Appendix 1)

A semiconductor device, comprising:

an upper surface electrode formed on a first main surface of a semiconductor substrate; and

a lower surface electrode formed on a second main surface on a side opposite to the first main surface and having main current flowing between the upper surface electrode and the lower surface electrode, wherein

the upper surface electrode includes:

a main output part outputting the main current in a plan view;

a sense part outputting sense potential for detecting the main current; and

a protruding part in which a part of the upper surface electrode protrudes toward an outer part, and

at least one of the sense part and the main output part is provided to a position other than the protruding part.

### (Appendix 2)

The semiconductor device according to Appendix 1, wherein at least a part of the protruding part is provided between the sense part and the main output part,

the sense part and the main output part output the sense potential and the main current via wires, respectively, and

a thickness of the protruding part is set in accordance with heights of the wires.

### (Appendix 3)

The semiconductor device according to Appendix 2, wherein

the upper surface electrode includes a first upper surface electrode and a second upper surface electrode disposed on the first upper surface electrode, and

the second upper surface electrode includes the protruding part partially protruding to the outer part.

### (Appendix 4)

The semiconductor device according to Appendix 2, wherein

the upper surface electrode includes a first upper surface electrode and a second upper surface electrode disposed on the first upper surface electrode,

the first upper surface electrode includes the protruding part partially protruding to the outer part, and

the second upper surface electrode is made up of a gold-plated film provided to cover the first upper surface electrode including the protruding part.

### (Appendix 5)

The semiconductor device according to Appendix 2, wherein

the upper surface electrode includes a first upper surface electrode and a second upper surface electrode disposed on the first upper surface electrode, and

the second upper surface electrode is bonded to the first upper surface electrode via a solder layer.

### (Appendix 6)

The semiconductor device according to Appendix 2, wherein

the upper surface electrode includes a first upper surface electrode and a second upper surface electrode partially disposed on the first upper surface electrode,

the second upper surface electrode functions as the protruding part, and

a thickness of the second upper surface electrode is set in accordance with the heights of the wires.

### (Appendix 7)

The semiconductor device according to Appendix 6, wherein the second upper surface electrode is bonded to the first upper surface electrode via a solder layer.

### (Appendix 8)

The semiconductor device according to any one of Appendixes 1 to 7, wherein the main output part is provided to a position other than the protruding part.

### (Appendix 9)

The semiconductor device according to any one of Appendixes 1 to 7, further comprising a bypass wire provided to extend over the protruding part.

### (Appendix 10)

The semiconductor device according to Appendix 1, wherein the protruding part has a striped shape extending in a first direction as a direction linearly connecting the sense part and the main output part in a plan view.

### (Appendix 11)

The semiconductor device according to Appendix 6, wherein the second upper surface electrode has a striped shape extending in a first direction as a direction linearly connecting the sense part and the main output part in a plan view.

While the disclosure has been shown and described in detail, the foregoing description is in all aspects illustrative and not restrictive. It is therefore understood that numerous modifications and variations can be devised.

What is claimed is:

1. A semiconductor device, comprising:
an upper surface electrode formed on a first main surface of a semiconductor substrate; and
a lower surface electrode formed on a second main surface on a side opposite to the first main surface and having main current flowing between the upper surface electrode and the lower surface electrode, wherein
the upper surface electrode includes:
a main output part outputting the main current in a plan view;
a sense part outputting sense potential for detecting the main current; and
a protruding part in which a part of the upper surface electrode protrudes toward an outer part, and
at least one of the sense part and the main output part is provided to a position other than the protruding part.

2. The semiconductor device according to claim 1, wherein
at least a part of the protruding part is provided between the sense part and the main output part,
the sense part and the main output part output the sense potential and the main current via wires, respectively, and
a thickness of the protruding part is set in accordance with heights of the wires.

3. The semiconductor device according to claim 2, wherein
the upper surface electrode includes a first upper surface electrode and a second upper surface electrode disposed on the first upper surface electrode, and
the second upper surface electrode includes the protruding part partially protruding to the outer part.

4. The semiconductor device according to claim 2, wherein
the upper surface electrode includes a first upper surface electrode and a second upper surface electrode disposed on the first upper surface electrode,
the first upper surface electrode includes the protruding part partially protruding to the outer part, and
the second upper surface electrode is made up of a gold-plated film provided to cover the first upper surface electrode including the protruding part.

5. The semiconductor device according to claim 2, wherein
the upper surface electrode includes a first upper surface electrode and a second upper surface electrode disposed on the first upper surface electrode, and
the second upper surface electrode is bonded to the first upper surface electrode via a solder layer.

6. The semiconductor device according to claim 2, wherein
the upper surface electrode includes a first upper surface electrode and a second upper surface electrode partially disposed on the first upper surface electrode,
the second upper surface electrode functions as the protruding part, and
a thickness of the second upper surface electrode is set in accordance with the heights of the wires.

7. The semiconductor device according to claim 6, wherein
the second upper surface electrode is bonded to the first upper surface electrode via a solder layer.

8. The semiconductor device according to claim 1, wherein
the main output part is provided to a position other than the protruding part.

9. The semiconductor device according to claim 1, further comprising
a bypass wire provided to extend over the protruding part.

10. The semiconductor device according to claim 1, wherein
the protruding part has a striped shape extending in a first direction as a direction linearly connecting the sense part and the main output part in a plan view.

11. The semiconductor device according to claim 6, wherein
the second upper surface electrode has a striped shape extending in a first direction as a direction linearly connecting the sense part and the main output part in a plan view.
